(19) United States
(12) Patent Application Publication
(10) Pub. No.: US 2017/0127566 A1
(43) Pub. Date: May 4, 2017

(54) COOLING STRUCTURE FOR ELECTRONIC COMPONENTS AND ELECTRIC COMPRESSOR

(71) Applicant: DENSO CORPORATION, Kariya-city, Aichi-pref. (JP)

(72) Inventors: Akihiro IMURA, Kariya-city (JP); Tsuyoshi TAKEMOTO, Kariya-city (JP)

(21) Appl. No.: 15/318,401

(22) PCT Filed: Aug. 7, 2015
(86) PCT No.: PCT/JP2015/003976

§ 371 Date: Dec. 13, 2016

(30) Foreign Application Priority Data
Aug. 29, 2014 (JP) 2014-175703

(51) Int. Cl. H05K 7/20; F25B 1/00

(52) U.S. Cl. CPC H05K 7/20354; F25B 1/00; H05K 7/20309; H05K 7/20881; H05K 7/20936

(57) ABSTRACT

A cooling structure for electronic components includes: a case having a refrigerant intake port and a refrigerant channel through which a refrigerant introduced from the refrigerant intake port flows, the refrigerant channel being formed by a wall section; a cooling section having a plurality of flat surfaces formed inside of the case in a manner to interpose the wall section between the flat surfaces and the refrigerant channel; and a plurality of electronic components arranged inside of the case and each of which is in contact with one of the flat surfaces. Each of the electronic components is cooled by the refrigerant via a corresponding flat surface of the flat surfaces and the wall section.

### CROSS REFERENCE TO RELATED APPLICATION

This application is based on Japanese Patent Application No. 2014-175703 filed on Aug. 29, 2014, the disclosure of which is incorporated herein by reference.

### TECHNICAL FIELD

The present disclosure relates to a cooling structure for electronic components and an electric compressor.

### BACKGROUND ART

An in-vehicle electric compressor is generally installed in a periphery of a traveling engine in an engine room, and thus a normal operation of an inverter circuit under a high-temperature atmosphere is essential. For this reason, an electric compressor that has a cooling structure for cooling the inverter circuit by using a refrigerant suctioned into the compressor has been suggested (for example, see Patent Literature 1).

More specifically, the electric compressor includes: a cylindrical housing that includes a refrigerant inlet port and a refrigerant discharge port; a compression mechanism that is accommodated in the housing to compress the refrigerant sucked from the refrigerant inlet port; an electric motor that is accommodated in the housing to drive the compression mechanism; and the inverter circuit that is attached to an axial end side of the housing to drive the electric motor.

A cooling plate is arranged between the axial end of the housing and the inverter circuit. A refrigerant passage, through which the refrigerant passes through, is provided between the axial end of the housing and the cooling plate, the refrigerant being sucked from the refrigerant inlet port and flowing toward the compression mechanism. The inverter circuit is cooled by the refrigerant in the refrigerant passage.

### PRIOR ART LITERATURES

### Patent Literature

Patent Literature 1: JP 2009-222009 A

### SUMMARY OF INVENTION

In the electric compressor of Patent Literature 1 described above, the refrigerant passage is formed between the axial end of the housing and the cooling plate, and the inverter circuit is cooled by the refrigerant in the refrigerant passage.

Meanwhile, in reality, downsizing of the electric compressor has been promoted. Accordingly, an installation space, in which electronic components for constituting the inverter circuit are installed, is limited. In addition to the above, of the electronic components, the electronic component that should be cooled the most is desirably arranged at a position that is suited for cooling. However, in order to achieve favorable assemblability of the electronic components, such arrangement may be difficult. Thus, there is a case where performance of the electric compressor cannot sufficiently be realized under the high-temperature environment.

The present disclosure has a purpose of providing a cooling structure for electronic components, and an electric compressor, in which the electronic components can be sufficiently cooled.

According to an aspect of the present disclosure, a cooling structure for electronic components includes: a case having a refrigerant intake port and a refrigerant channel through which a refrigerant introduced from the refrigerant intake port flows, the refrigerant channel being formed by a wall section; a cooling section having a plurality of flat surfaces inside of the case in a manner to interpose the wall section between the flat surfaces and the refrigerant channel; and a plurality of electronic components arranged inside of the case and each of which is in contact with one of the flat surfaces. Each of the electronic components is cooled by the refrigerant via a corresponding flat surface of the flat surfaces and the wall section.

According to the above, the cooling section is constructed of the flat surfaces. Thus, each of the electronic components can be brought into contact with an appropriate flat surface of the flat surfaces in accordance with a physical constitution thereof. Therefore, the electronic components can sufficiently be cooled.

The wall section means a portion of the case that is filled with a material for constituting the case.

### BRIEF DESCRIPTION OF DRAWINGS

The above and other objects, features and advantages of the present disclosure will become more apparent from the following detailed description made with reference to the accompanying drawings.

FIG. 1 is a perspective view of exploded states of a compressor section and an inverter device in an in-vehicle electric compressor according to a first embodiment.

FIG. 2 is a schematic view of a configuration of the in-vehicle electric compressor of the first embodiment.

FIG. 3 is a cross-sectional view of a single body of a plate in FIG. 1.

FIG. 4 is a view in which the single body of the plate in FIG. 1 is seen from the other side in an axial direction.

FIG. 5 is a top view of an inverter case of the inverter device in FIG. 1.

FIG. 6 is a cross-sectional view of the inverter device in FIG. 1.

FIG. 7 is a view in which a single body of the inverter case of the inverter device in FIG. 1 is seen from the other side in the axial direction.

FIG. 8 is a view in which the inverter device in FIG. 1 is seen from one side in the axial direction.

FIG. 9 is a view in which inside of the inverter device in FIG. 1 is seen from the other side in the axial direction.

FIG. 10 is an electric circuit diagram that depicts a configuration of an electric circuit in the inverter device in FIG. 1.

FIG. 11 is a view in which a single body of an inverter case of an inverter device according to a second embodiment is seen from the other side in an axial direction.

FIG. 12 is a view in which the inverter device in FIG. 11 is seen from one side in the axial direction.

FIG. 13 is a cross-sectional view of the inverter device in FIG. 11.

FIG. 14 is a view in which a single body of a plate in FIG. 13 is seen from the other side in the axial direction.

FIG. 15 is a cross-sectional view of the single body of the plate in FIG. 13.

FIG. 16 is a cross-sectional view of an inverter device according to a third embodiment.

### DESCRIPTION OF EMBODIMENTS

Hereinafter, embodiments will be described according to the drawings. Same or equivalent portions among respective embodiments below are labeled with same reference numerals in the drawings.

### First Embodiment

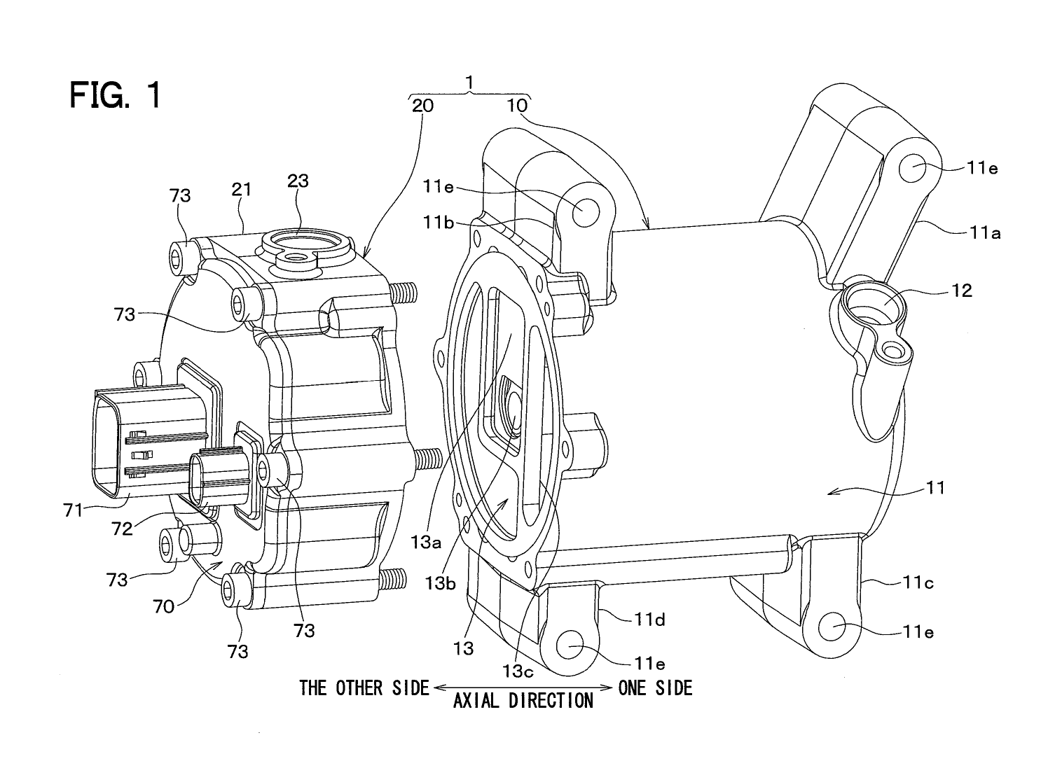

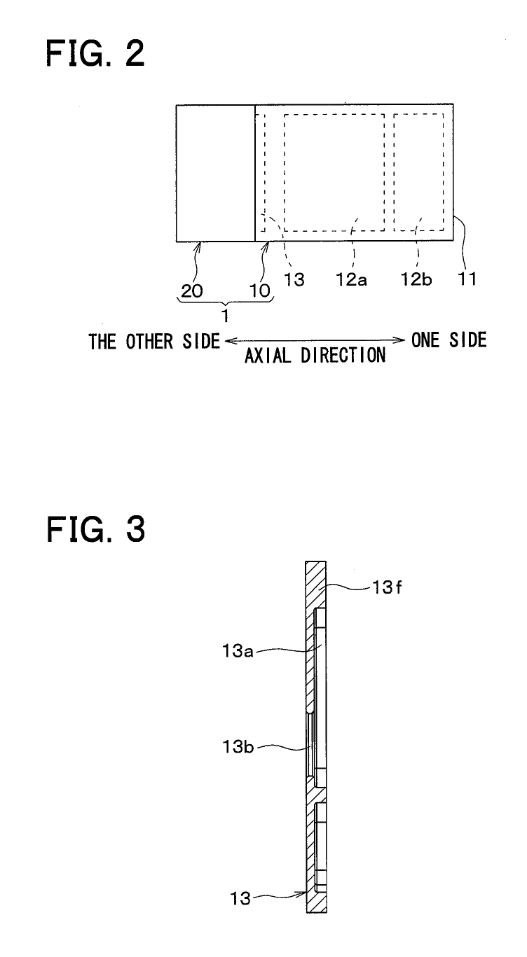

FIG. 1 and FIG. 2 illustrate an in-vehicle electric compressor 1 according to a first embodiment, into which a cooling structure for electronic components is applied.

The in-vehicle electric compressor 1 shown in FIG. 1 configures a well-known refrigeration cycle apparatus for circulating a refrigerant together with a cooling device, a pressure reducing valve, and an evaporator, and includes a compressor section 10 and an inverter device 20. The compressor section 10 includes a compressor housing 11. The compressor housing 11 is formed in a cylindrical shape, one side of which in an axial direction is closed. A refrigerant discharge port 12 is provided on the one side in the axial direction of the compressor housing 11.

The compressor housing 11 has legs 11a, 11b, 11c, 11d. A through hole 11e that is penetrated by a bolt (not depicted) is provided in each of the legs 11a, 11b, 11c, 11d. The bolts are used to fix the compressor housing 11 to a traveling engine.

An opening is formed on the other side in the axial direction of the compressor housing 11. A disc-shaped plate 13 is fitted to the opening.

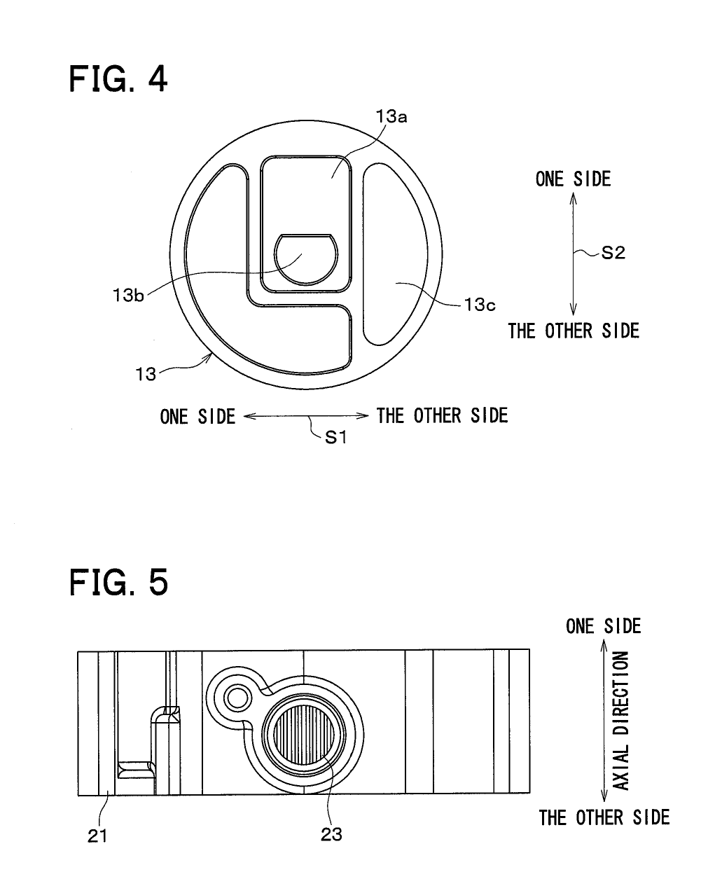

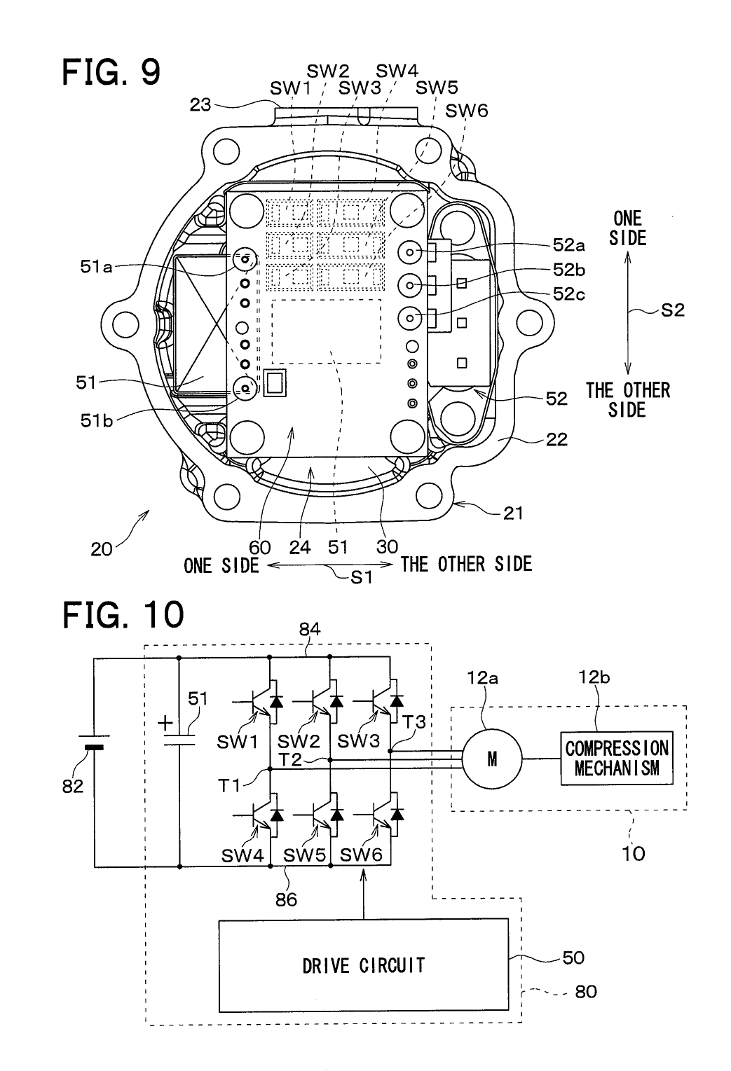

As depicted in FIG. 3 and FIG. 4, a groove 13a is formed on the other side in the axial direction of the plate 13. On a central side of the plate 13, the groove 13a is formed to be recessed to the one side in the axial direction. The groove 13a constitutes a channel 40 with a recessed section 29 of an inverter case 21. The plate 13 has a refrigerant outlet port 13b and a through hole 13c. The refrigerant outlet port 13b is formed to penetrate the groove 13a. The refrigerant outlet port 13b is a hole for guiding the refrigerant into the compressor housing 11, the refrigerant being suctioned from a refrigerant intake port 23, which will be described below. The through hole 13c is provided to accommodate an airtight terminal 52, which is depicted in FIG. 9. The airtight terminal 52 is a terminal for electrically connecting a circuit board 60 in the inverter device 20 and an electric motor 12a. The electric motor 12a is accommodated in the compressor housing 11 and drives a compression mechanism 12b. The electric motor 12a of the present embodiment constitutes a three-phase AC motor of a synchronous type. The compression mechanism 12b is accommodated in the compressor housing 11, compresses the refrigerant that is suctioned from the refrigerant intake port 23, which will be described below, and discharges the refrigerant from the refrigerant discharge port 12 toward the cooling device.

The inverter device 20 includes the inverter case 21. The inverter case 21 is arranged on the other side of the compressor section 10 in the axial direction. The inverter case 21 is formed in a short cylindrical shape. The inverter case 21 is arranged such that an axis thereof corresponds to an axis of the compressor housing 11.

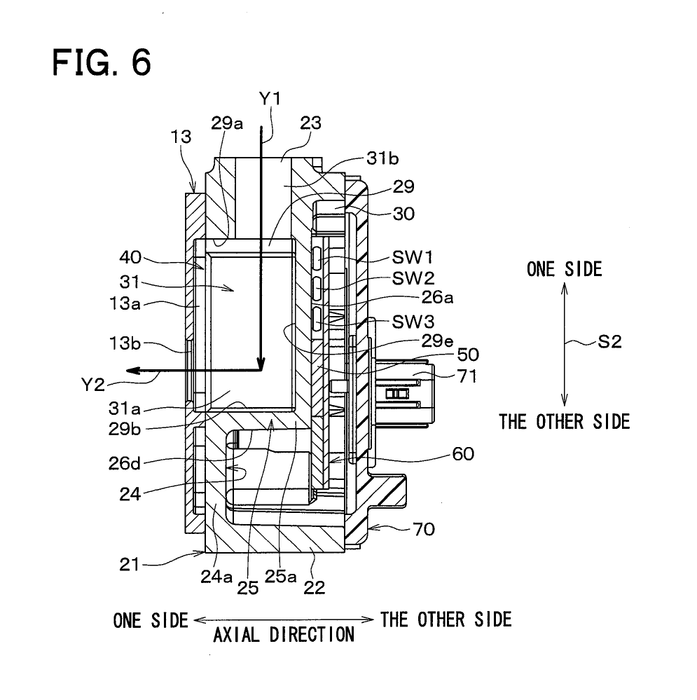

The inverter case 21 includes a side wall 22 that is formed in an annular shape with the axis thereof being the center. The side wall 22 has the refrigerant intake port 23 (see FIG. 5, FIG. 6).

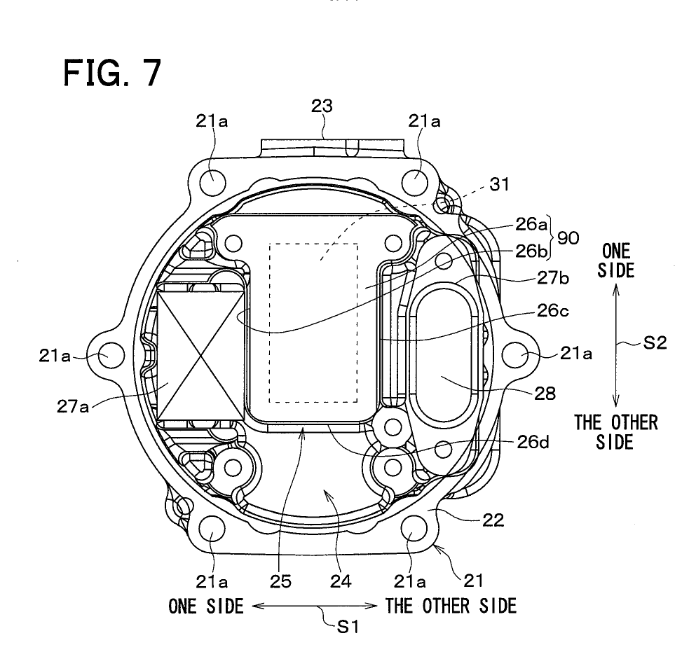

As depicted in FIG. 6, an opening 30 is formed on the other side in the axial direction of the side wall 22. As depicted in FIG. 7, one side in the axial direction of the side wall 22 is closed by a bottom section 24 and a projected section 25. FIG. 7 is a view in which a single body of the inverter case 21 is seen from the other side in the axial direction. That is, FIG. 7 is a view of the inverter case 21 in a state where switching elements SW1, SW2, SW3, SW4, SW5, SW6, a drive circuit 50, a capacitor 51, and the airtight terminal 52 are removed therefrom.

The projected section 25 is formed to be projected from the bottom section 24 to the other side in the axial direction. As depicted in FIG. 7, when seen from the other side in the axial direction, the projected section 25 is formed in a rectangular shape that extends from the refrigerant intake port 23 of the side wall 22 to an axial center side (a lower side in FIG. 7). That is, in the inverter case 21, the projected section 25 is formed in a rectangular parallelepiped shape.

A rectangular flat surface 26a (a first flat surface) is formed on the other side in the axial direction (that is, on the side adjacent to the opening 30) of the projected section 25. Side surfaces 26b, 26c, 26d as flat surfaces are formed on the projected section 25 on the side adjacent to the side wall 22. Each of the side surfaces 26b, 26c, 26d is formed to intersect the flat surface 26a. The side surface 26b (a second flat surface) is formed on one side in a radial direction S1. The radial direction S1 is a radial direction with the axial center of the inverter case 21 being the center. The side surface 26c is formed on the other side in the radial direction S1. The radial direction S1 is a direction that intersects a radial direction S2 at right angles, the radial direction S2 connecting the refrigerant intake port 23 and the axial center. The side surface 26d is formed on an opposite side of the refrigerant intake port 23 in the radial direction S2.

A flat surface 27a (a third flat surface) is formed on the one side in the radial direction S1 of the bottom section 24. A flat surface 27b is formed on the other side in the radial direction S2 of the bottom section 24. A through hole 28 is formed on the other side in the radial direction S1 of the bottom section 24. The through hole 28 is formed to communicate with the through hole 13c of the plate 13. The through holes 28, 13c each constitute the hole for accommodating the airtight terminal 52.

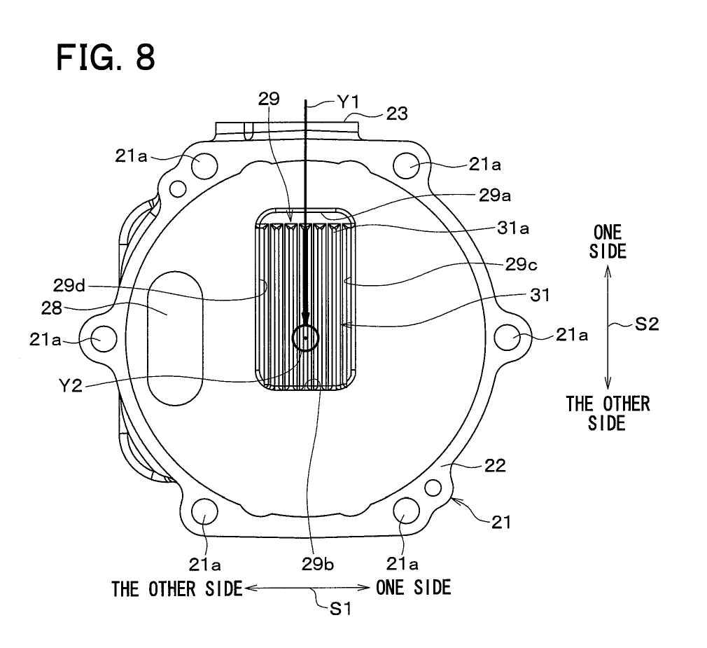

The recessed section 29 (see FIG. 6, FIG. 8) that is recessed to the other side in the axial direction is formed on the one side in the axial direction of the projected section 25.

The recessed section 29 is formed by a wall section 25a and is constructed of side surfaces 29a, 29b, 29c, 29d and a ceiling surface 29e. The wall section 25a is not a portion of the inverter case 21 that is filled with the refrigerant or air but is a portion of the inverter case 21 that is filled with a metallic material for constituting the inverter case 21. The wall section 25a indicates a wall section of the inverter case 21 that constitutes the projected section 25.

The side surface 29a is formed on one side in the radial direction S2. A through hole 31b that communicates with the refrigerant intake port 23 is opened in the side surface 29a. That is, the inside of the recessed section 29 communicates with the refrigerant intake port 23. The side surface 29b is formed on the other side in the radial direction S2. The side surface 29c is formed on the one side in the radial direction S1. The side surface 29d is formed on the other side in the radial direction S1. The ceiling surface 29e is formed on the other side in the axial direction.

In a state of being closed by the groove 13a of the plate 13, the recessed section 29, which is configured just as described, constitutes the channel 40. The channel 40 is formed by the wall section 25a of the inverter case 21 and a wall section 13f of the plate 13. The wall section 13f is a portion of the plate 13 that is filled with a metallic material for constituting the plate 13. A cooling fin 31 is provided in the channel 40. The cooling fin 31 promotes heat exchange between the refrigerant in the channel 40 and cooling targets. The cooling targets of the present embodiment are the switching elements SW1, SW2, SW3, SW4, SW5, SW6, the drive circuit 50, and the capacitor 51.

More specifically, the cooling fin 31 is constructed of thin plate materials 31a. Each of the thin plate materials 31a is formed in a thin film shape that extends in the radial direction S2 and the axial direction. The thin plate materials 31a are aligned in the radial direction S1. Between the two adjacent thin plate materials 31a of the thin plate materials 31a, a channel, through which the refrigerant suctioned from the refrigerant intake port 23 flows toward the refrigerant outlet port 13b as indicated by arrows Y1, Y2 in FIG. 6 and FIG. 8, is formed for two each of the adjacent thin plate materials 31a. The arrow Y2 in FIG. 8 indicates a state where a flow (the arrow) of the refrigerant is directed to a near side in a perpendicular direction of the sheet. Each of the thin plate materials 31a is supported by the side surface 29b and the ceiling surface 29e.

In the present embodiment that is configured as described above, the flat surface 26a and the side surfaces 26b, 26c, 26d of the projected section 25 are formed to surround the cooling fin 31.

The switching elements SW1, SW2, SW3, SW4, SW5, SW6, the drive circuit 50, the capacitor 51, and the airtight terminal 52 are arranged in the inverter case 21.

Each of the switching elements SW1, SW2, SW3, SW4, SW5, SW6 is formed in a thin film shape. The drive circuit 50 is formed in a thin film shape. Each of the switching elements SW1, SW2, SW3, SW4, SW5, SW6 and the drive circuit 50 is in contact with the flat surface 26a of the projected section 25. The switching elements SW1 to SW6 are arrayed in matrix of (2×3) on the flat surface 26a adjacent to the refrigerant intake port 23. The drive circuit 50 is arranged on the flat surface 26a adjacent to the refrigerant outlet port 13b (a lower side in FIG. 9) with respect to the switching elements SW1 to SW6.

Each of the switching elements SW1, SW2, SW3, SW4, SW5, SW6 and the drive circuit 50 of the present embodiment is mounted on the circuit board 60. In the inverter case 21, the circuit board 60 is arranged on the other side in the axial direction with respect to the switching elements SW1 to SW6 and the drive circuit 50.

In the inverter case 21, the capacitor 51 is arranged on the one side in the radial direction S1 with respect to the projected section 25. The capacitor 51 is formed in a rectangular parallelepiped shape and is in contact with the side surface 26b and the flat surface 27a. The capacitor 51 is connected to the circuit board 60 via terminals 51a, 51b. The terminals 51a, 51b are arranged on the other side in the axial direction of the capacitor 51.

The switching elements SW1, SW2, SW3, SW4, SW5, SW6, the drive circuit 50, and the capacitor 51 constitute an inverter circuit that outputs a three-phase AC current to the electric motor 12a. A configuration of an electric circuit in the inverter circuit will be described below.

In the inverter case 21, the airtight terminal 52 is arranged on the other side in the radial direction S1 with respect to the projected section 25. The airtight terminal 52 is connected to the circuit board 60 via terminals 52a, 52b, 52c. The terminals 52a, 52b, 52c are arranged on the other side in the axial direction of the airtight terminal 52.

As depicted in FIG. 1, the inverter device 20 includes a lid 70. The lid 70 is formed to close the opening 30 of the inverter case 21. Connectors 71, 72 are connected to the lid 70. The connectors 71, 72 are connected to the circuit board 60.

The lid 70 is fixed to the compressor housing 11 by units (six in FIG. 1) of bolts 73. Each of the units (six in FIG. 1) of the bolts 73 is fastened to the compressor housing 11 through a through hole 21a (see FIG. 9) of the inverter case 21. In this way, the inverter case 21 and the lid 70 are fixed to the compressor housing 11 by the units of the bolts 73.

Each of the compressor housing 11, the plate 13, the inverter case 21, and the cooling fin 31 (32, 33) of the present embodiment is molded from a metallic material, such as aluminum, stainless steel (SUS), or cast iron.

Next, a description will be made on a configuration of an electric circuit in an inverter circuit 80 of the present embodiment with reference to FIG. 10.

Transistors SW1, SW3, SW5 are connected to a positive electrode bus 84. A positive electrode of a high-voltage power supply 82 is connected to the positive electrode bus 84. Transistors SW2, SW4, SW6 are connected to a negative electrode bus 86. A negative electrode of the high-voltage power supply 82 is connected to the negative electrode bus 86.

The transistors SW1, SW2 are connected in series between the positive electrode bus 84 and the negative electrode bus 86. The transistors SW3, SW4 are connected in series between the positive electrode bus 84 and the negative electrode bus 86. The transistors SW5, SW6 are connected in series between the positive electrode bus 84 and the negative electrode bus 86.

A common connection terminal T1 between the transistors SW1, SW2 is connected to a U-phase coil of a stator coil of the electric motor 12a. A common connection terminal T2 between the transistors SW3, SW4 is connected to a V-phase coil of the stator coil of the electric motor 12a. A common connection terminal T3 between the transistors SW5, SW6 is connected to a W-phase coil of the stator coil of the electric motor 12a. Each of the transistors SW1, SW2, SW3, SW4, SW5, SW6 is constructed of any of various types of semiconductor switching elements, such as an insulated gate bipolar transistor (an IGBT), and a reflux diode. The capacitor 51 is connected between the positive electrode bus 84 and the negative electrode bus 86 of the inverter circuit 80 and stabilizes a voltage that is provided between the positive electrode bus 84 and the negative electrode bus 86 from the high-voltage power supply 82. The drive circuit 50 controls the switching elements SW1, SW2, SW3, SW4, SW5, SW6.

In the present embodiment that is configured as described above, the flat surface 26a and the side surface 26b of the projected section 25 constitute a cooling section 90 for cooling the capacitor 51, the drive circuit 50, and the switching elements SW1 to SW6.

Next, a description will be made on a manufacturing method of the inverter device 20 of the present embodiment.

First, the capacitor 51 and the airtight terminal 52 are accommodated in the inverter case 21. At this time, the capacitor 51 is brought into contact with the side surface 26b of the projected section 25 and the flat surface 27a. The airtight terminal 52 is fixed to the flat surface 27b of the inverter case 21 in a state of being fitted to the through holes 28, 13c.

Next, the circuit board 60, on which the switching elements SW1 to SW6 and the drive circuit 50 are mounted in advance, is accommodated in the inverter case 21. At this time, the switching elements SW1 to SW6 and the drive circuit 50 are arrayed on the flat surface 26a of the projected section 25. In this way, the switching elements SW1 to SW6 and the drive circuit 50 are brought into contact with the flat surface 26a of the projected section 25. In this state, the circuit board 60 is fixed to the inverter case 21.

Next, the lid 70 is arranged on the inverter case 21 so as to close the opening 30 of the inverter case 21. The lid 70 and the inverter case 21 are fixed to the compressor housing 11 by the units of the bolts 73.

Next, a description will be made on an operation of the inverter device 20 of the present embodiment.

First, the drive circuit 50 controls the switching elements SW1, SW2, SW3, SW4, SW5, SW6. Accordingly, each of the switching elements SW1 to SW6 performs switching. In conjunction with this, the three-phase AC current is output from the common connection terminals T1, T2, T3 to the stator coil of the electric motor 12a on the basis of the output voltage of the capacitor 51. At this time, the electric motor 12a outputs rotational output thereof to the compression mechanism 12b. Thus, the compression mechanism 12b is driven by the electric motor 12a and performs an operation of compressing the refrigerant. At this time, the refrigerant from the evaporator side passes through the refrigerant intake port 23, the through hole 31b, the channel 40, the refrigerant outlet port 13b of the plate 13, and the electric motor 12a and is suctioned to the compression mechanism 12b. The compression mechanism 12b compresses the suctioned refrigerant and discharges the high-temperature, high-pressure refrigerant from the refrigerant discharge port 12 toward the cooling device.

Each of the switching elements SW1, SW2, SW3, SW4, SW5, SW6, the capacitor 51, and the drive circuit 50 generates heat. Meanwhile, each of the switching elements SW1 to SW6 and the drive circuit 50 exchanges heat with the refrigerant in the channel 40 via the wall section 25a and the flat surface 26a of the projected section 25. Accordingly, the switching elements SW1 to SW6 and the drive circuit 50 are cooled by the refrigerant in the channel 40.

The heat is exchanged between the capacitor 51 and the refrigerant in the channel 40 via the wall section 25a and the side surface 26b of the projected section 25. Accordingly, the capacitor 51 is cooled by the refrigerant in the channel 40.

According to the present embodiment that has been described so far, the inverter device 20 includes the inverter case 21, the switching elements SW1, SW2, SW3, SW4, SW5, SW6, the drive circuit 50, and the capacitor 51. The side wall 22 of the inverter case 21 has the refrigerant intake port 23. The one side in the axial direction of the side wall 22 is closed by the bottom section 24 and the projected section 25. The recessed section 29 that is recessed to the other side in the axial direction is formed on the one side in the axial direction of the projected section 25. In the state of being closed by the groove 13a of the plate 13, the recessed section 29 constitutes the channel 40. The channel 40 is formed by the wall section 25a of the inverter case 21 and the wall section 13f of the plate 13. The channel 40 communicates with the refrigerant intake port 23 through the through hole 31b and also communicates with the refrigerant outlet port 13b of the plate 13. Along with the compressing operation of the compression mechanism 12b, the refrigerant flows in an order of the refrigerant intake port 23, the through hole 31b, the channel 40, the refrigerant outlet port 13b of the plate 13, and the compression mechanism 12b. In this way, the refrigerant channel is three-dimensionally configured in the inverter case 21.

The drive circuit 50 and the switching elements SW1 to SW6 are in contact with the flat surface 26a of the projected section 25. The capacitor 51 is in contact with the side surface 26b of the projected section 25. Just as described, the flat surface 26a and the side surface 26b of the projected section 25 constitute the cooling section 90 for cooling the capacitor 51, the drive circuit 50, and the switching elements SW1 to SW6. The drive circuit 50 and the switching elements SW1, . . . SW6 are cooled by the refrigerant in the channel 40 via the flat surface 26a and the wall section 25a. The capacitor 51 is cooled by the refrigerant in the channel 40 via the wall section 25a and the side surface 26b of the projected section 25.

According to what has been described so far, each of the drive circuit 50, the capacitor 51, and the switching elements SW1 to SW6 can be brought into contact with an appropriate flat surface of the flat surface 26a and the side surface 26b of the projected section 25 in accordance with a physical constitution thereof. Accordingly, the drive circuit 50, the capacitor 51, and the switching elements SW1 to SW6 can sufficiently be cooled in the electric compressor. Thus, the inverter circuit 80, which is constructed of the switching elements SW1 to SW6, the drive circuit 50, and the capacitor 51, can be sufficiently cooled under a high-temperature environment in an engine room, and performance of the in-vehicle electric compressor 1 can be improved in a wide range. Therefore, a frequency at which the inverter circuit 80 is stopped due to a temperature constraint can be reduced.

In the present embodiment, the switching elements SW1 to SW6 are arranged in a portion that is closer to the refrigerant intake port 23 than the drive circuit 50 and the capacitor 51. The switching elements SW1 to SW6 generate a larger amount of heat generation than the drive circuit 50 and the capacitor 51.

Accordingly, the switching elements SW1 to SW6 are arranged in the portion that is closer to the refrigerant intake port 23 than the drive circuit 50 and the capacitor 51, each of which generates the smaller amount of heat generation than the switching elements SW1 to SW6. Thus, a sufficient cooling effect of the switching elements SW1 to SW6 can be obtained. Therefore, heat resistance of the entire inverter circuit (the electronic circuit) 80 can be improved.

In the present embodiment, the switching elements SW1 to SW6 generate the larger amount of heat generation than the drive circuit 50 and the capacitor 51. Accordingly, the switching elements SW1 to SW6 are required to be cooled the most in comparison with the drive circuit 50 and the capacitor 51. For this reason, in the present embodiment, the switching elements SW1 to SW6 are arranged on the flat surface 26a of the projected section 25, the flat surface 26a being formed on the other side in the axial direction. Thus, the switching elements SW1 to SW6 can proactively and easily be arranged far from the compressor housing 11 as a heat generating body, and heat insulation performance is thereby improved.

In the present embodiment, the cooling fin 31 is arranged in the channel 40. Accordingly, the heat exchange between the refrigerant and each of the switching elements SW1 to SW6, the drive circuit 50, and the capacitor 51 is promoted. Thus, the switching elements SW1 to SW6, the drive circuit 50, and the capacitor 51 can reliably be cooled.

In the present embodiment, the flat surface 26a and the side surfaces 26b, 26c, 26d of the projected section 25 are formed to surround the cooling fin 31. Thus, the flat surface 26a and the side surfaces 26b, 26c, 26d as cooling surfaces can three-dimensionally be configured, and the number of electronic components as the cooling targets can easily be increased.

### Second Embodiment

In the above first embodiment, the description has been made in which the capacitor 51 is cooled by the refrigerant in the channel 40 via the side surface 26b of the projected section 25. In addition to the above, a description will be made in which a capacitor 51 of a second embodiment is cooled by a refrigerant via a bottom section 24.

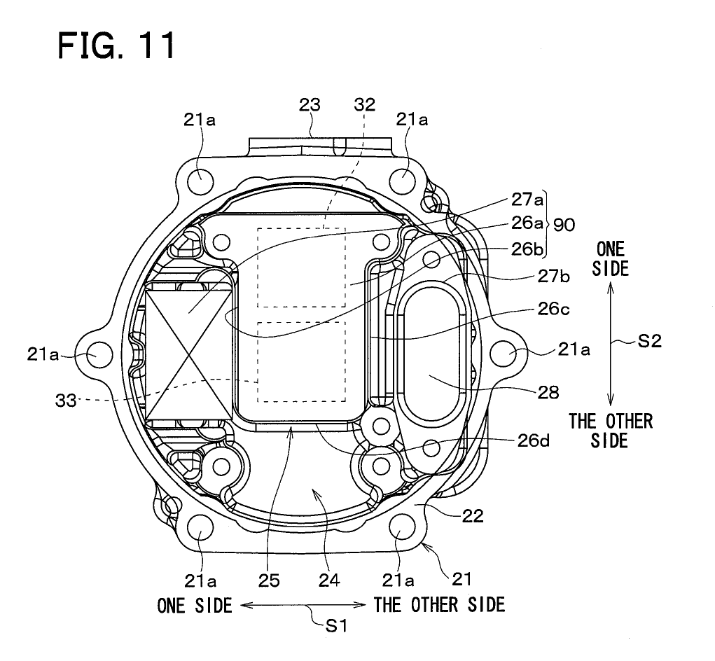

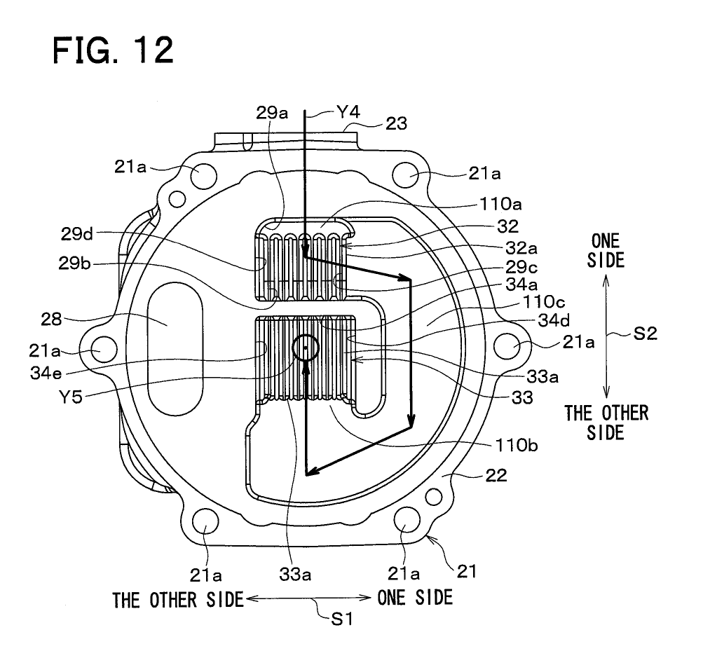

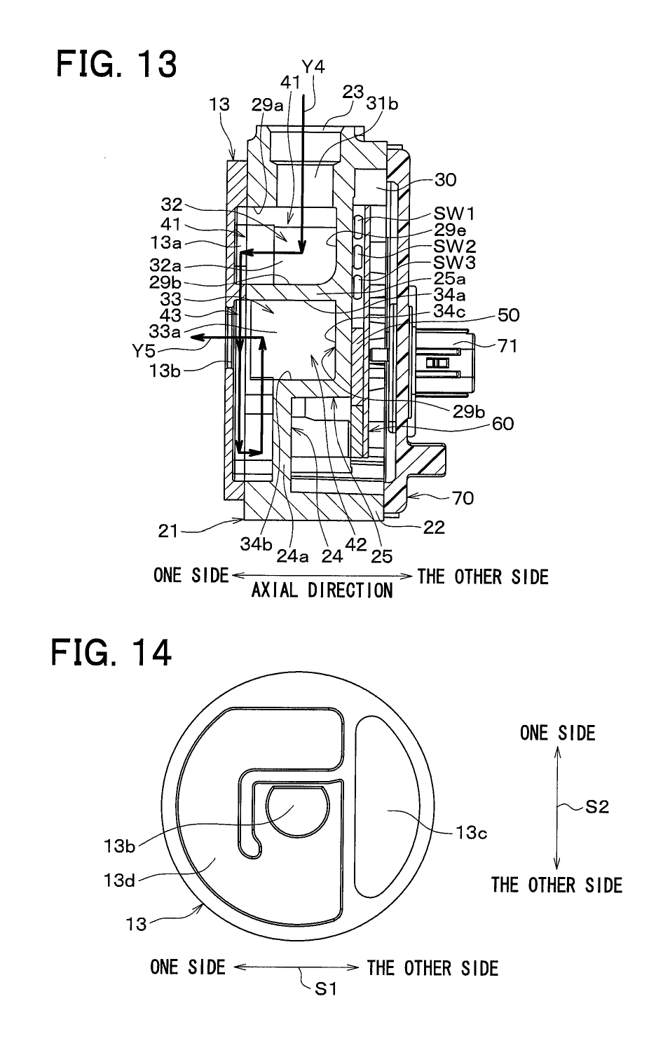

FIG. 11, FIG. 12, and FIG. 13 depict an inverter device 20 of the second embodiment. FIG. 11 is a view in which inside of a single body of an inverter case 21 of the present embodiment is seen from the other side in an axial direction. FIG. 12 is a view in which the single body of the inverter case 21 is seen from one side in the axial direction. FIG. 13 is a cross-sectional view of the inside of the inverter device 20.

Similar to the above first embodiment, the inverter case 21 has the bottom surface 24 and a projected section 25. The projected section 25 has recessed sections 110a, 110b. Each of the recessed sections 110a, 110b is formed by a wall section 25a and is formed to be recessed from the one side in the axial direction to the other side in the axial direction of the projected section 25. The recessed section 110a (a first recessed section) is arranged adjacent to a refrigerant intake port 23 with respect to the recessed section 110b. The recessed section 110b (a second recessed section) is formed adjacent to an axial center of the inverter case 21.

As depicted in FIG. 12, a groove 110c (a third recessed section) is formed on the one side in the axial direction with respect to the bottom section 24 in the inverter case 21. The groove 110c is formed by a wall section 24a and is formed to extend between the recessed sections 110a, 110b on the side adjacent to the bottom section 24. That is, the groove 110c is formed to bypass the portion between the recessed sections 110a, 110b in an inverted C-shape when seen from the one side in the axial direction. Similar to the wall section 25a, the wall section 24a of the present embodiment is a portion of the inverter case 21 that is filled with a metallic material for constituting the inverter case 21. The wall section 24a indicates a wall section of the inverter case 21 that constitutes the bottom section 24.

As depicted in FIG. 13, similar to the above first embodiment, a plate 13 is arranged on the one side in the axial direction of the inverter case 21.

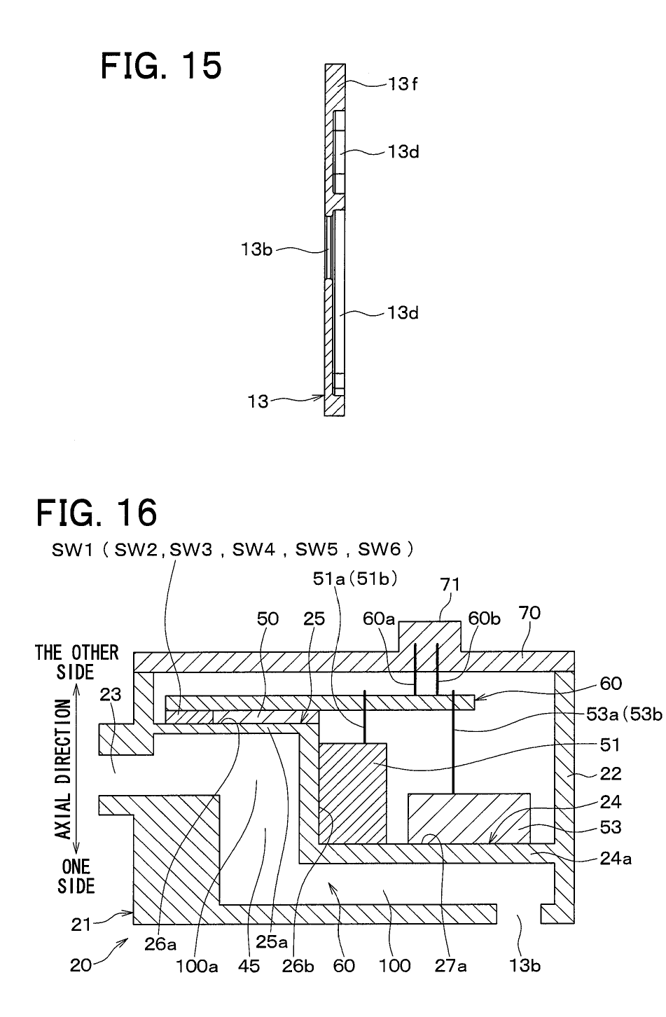

As depicted in FIG. 14 and FIG. 15, a groove 13d is formed on the one side in the axial direction of the plate 13 of the present embodiment. As depicted in FIG. 14, the groove 13d is formed in a C-shape when seen from the other side in the axial direction. The groove 13d is formed with a refrigerant outlet port 13b. The refrigerant outlet port 13b is arranged on and penetrates an axial center side of the plate 13 in the axial direction. The groove 13d is formed to overlap the recessed section 110a, the groove 110c, and the recessed section 110b in the axial direction.

The recessed section 110a and the groove 13d constitute a channel 41 (a first channel). The recessed section 110b and the groove 13d constitute a channel 42 (a second channel). The groove 110c and the groove 13d constitute a bypass channel 43. The bypass channel 43 constitutes a refrigerant channel that communicates with the channels 41, 42 and bypasses toward the bottom section 24.

The recessed section 110a is formed by side surfaces 29a, 29b, 29c, 29d and a ceiling surface 29e. The recessed section 110b is formed by side surfaces 34a, 34b, 34d, 34e and a ceiling surface 34c.

A cooling fin 32 is provided in the channel 41. The cooling fin 32 is constructed of thin plate materials 32a. Each of the thin plate materials 32a is formed in a thin film shape that extends in a radial direction S2 and the axial direction. The thin plate materials 32a are aligned in a radial direction S1. Between the two adjacent thin plate materials 32a of the thin plate materials 32a, a channel, through which the refrigerant suctioned from the refrigerant intake port 23 flows toward the bypass channel 43 as indicated by arrows Y4, Y5 in FIG. 12 and FIG. 13, is formed for two each of the adjacent thin plate materials 32a. Each of the thin plate materials 32a is supported by the side surface 29b and the ceiling surface 29e.

A cooling fin 33 is provided in the channel 42. The cooling fin 33 is constructed of thin plate materials 33a. Each of the thin plate materials 33a is formed in a thin film shape that extends in the radial direction S2 and the axial direction. The thin plate materials 33a are aligned in the radial direction S1. Between the two adjacent cooling fins 33 of the thin plate materials 33a, a channel, through which the refrigerant flows from the bypass channel 43 toward the refrigerant outlet port 13b, is formed for two each of the cooling fins 33 as indicated by the arrows Y4, Y5 in FIG. 12 and FIG. 13. Each of the thin plate materials 33a is supported by the side surface 34a and the ceiling surface 34c.

In the present embodiment that is configured as described above, the flat surface 26a and the side surfaces 26b, 26c, 26d of the projected section 25 are formed to surround the cooling fins 32, 33. Similar to the above first embodiment, switching elements SW1 to SW6 and a drive circuit 50 of the present embodiment are in contact with the flat surface 26a of the projected section 25. The capacitor 51 is in contact with the side surface 26b of the projected section 25 and a flat surface 27a of the bottom section 24.

The side surface 26b and the flat surface 26a of the projected section 25 and the flat surface 27a of the bottom section 24 constitute a cooling section 90 for cooling the capacitor 51, the drive circuit 50, and the switching elements SW1 to SW6.

Next, a description will be made on an operation of the inverter device 20 of the present embodiment.

In the present embodiment, when a compression mechanism 12b is driven by an electric motor 12a and performs an operation of compressing the refrigerant, the refrigerant from an evaporator side flows in an order of the refrigerant intake port 23, a through hole 31b, the channel 41, the bypass channel 43, and the channel 42. The refrigerant flows into a compressor housing 11 from the refrigerant outlet port 13b.

At this time, the switching elements SW1 to SW6 are cooled by the refrigerant in the channel 41 via the wall section 25a and the flat surface 26a of the projected section 25. The drive circuit 50 is cooled by the refrigerant in the channel 42 via the wall section 25a and the flat surface 26a of the projected section 25. The capacitor 51 is cooled by the refrigerant in the channel 42 via the wall section 25a and the side surface 26b of the projected section 25. The capacitor 51 is cooled by the refrigerant in the bypass channel 43 via the wall section 24a and the flat surface 27a of the bottom section 24.

According to the present embodiment that has been described so far, each of the drive circuit 50, the capacitor 51, and the switching elements SW1 to SW6 can be brought into contact with an appropriate flat surface of the flat surface 26a and the side surface 26b of the projected section 25 and the flat surface 27a of the bottom section 24 in accordance with a physical constitution thereof. Accordingly, similar to the above first embodiment, the drive circuit 50, the capacitor 51, and the switching elements SW1 to SW6 can sufficiently be cooled.

In particular, in the present embodiment, the capacitor 51 is cooled by the refrigerant in the channels 41, 42 and the refrigerant in the bypass channel 43. Accordingly, cooling performance for cooling the capacitor 51 can be improved.

In the present embodiment, the cooling fin 32 is arranged in the channel 41. The cooling fin 33 is arranged in the channel 42. Accordingly, heat exchange between the refrigerant and each of the switching elements SW1 to SW6, the drive circuit 50, and the capacitor 51 is promoted. Thus, the switching elements SW1 to SW6, the drive circuit 50, and the capacitor 51 can reliably be cooled.

### Third Embodiment

In the above first and second embodiments, the description has been made in which the refrigerant channel is constructed of the plate 13 and the inverter case 21. Instead of the above, in a third embodiment, a refrigerant channel is constructed of a single body of an inverter case 21.

FIG. 16 is a cross-sectional view of an inverter device 20 of the third embodiment. In FIG. 16, the same reference sign as that in FIG. 6 denote the same component. Similar to the above first embodiment, in the inverter case 21 of the inverter device 20 of the present embodiment, one side in an axial direction of a side wall 22 is closed by a bottom section 24 and a projected section 25. The inverter case 21 defines a refrigerant channel 100. The refrigerant channel 100 is formed by the single body of the inverter case 21. That is, the refrigerant channel 100 is formed irrespective of a plate 13. The refrigerant channel 100 is formed by wall sections 25a, 24a of the inverter case 21. Each of the wall sections 25a, 24a is a portion of the inverter case 21 that is filled with a metallic material for constituting the inverter case 21. The wall section 25a is a wall section of the projected section 25 that forms the refrigerant channel 100. The wall section 24a is a wall section of the bottom section 24 that forms the refrigerant channel 100.

A refrigerant intake port 23 of the refrigerant channel 100 is formed in the side wall 22. A refrigerant outlet port 13b of the refrigerant channel 100 is arranged on one side in an axial direction of the inverter case 21. The refrigerant outlet port 13b is opened to the one side in the axial direction.

The refrigerant channel 100 is formed along a flat surface 26a of the projected section 25, a side surface 26b, and a flat surface 27a of the bottom section 24.

A drive circuit 50 and switching elements SW1 to SW6 are in contact with the flat surface 26a of the projected section 25. A capacitor 51 is in contact with the side surface 26b of the projected section 25 and the flat surface 27a of the bottom section 24. A coil 53 is in contact with the flat surface 27a of the bottom section 24 and smoothes a voltage between both terminals of the capacitor 51. The coil 53 constitutes an inverter circuit 80 with the switching elements SW1, SW2, SW3, SW4, SW5, SW6, the drive circuit 50, and the capacitor 51.

Just as described, the flat surface 26a of the projected section 25, the side surface 26b and the flat surface 27a of the bottom section 24 constitute a cooling section 90 for cooling the capacitor 51, the drive circuit 50, the coil 53, and the switching elements SW1 to SW6.

The drive circuit 50 and the switching elements SW1 to SW6 are cooled by the refrigerant in the refrigerant channel 100 via the flat surface 26a and the wall section 25a. The capacitor 51 is cooled by the refrigerant in the refrigerant channel 100 via the wall section 25a and the side surface 26b of the projected section 25. Each of the capacitor 51 and the coil 53 is cooled by the refrigerant in the refrigerant channel 100 via the wall section 24a and the flat surface 27a of the bottom section 24.

A channel cross-sectional area of a refrigerant channel 100a that is formed adjacent to the projected section 25 of the refrigerant channel 100 differs from a channel cross-sectional area of a refrigerant channel 100b that is formed adjacent to the bottom section 24 of the refrigerant channel 100. More specifically, the channel cross-sectional area of the refrigerant channel 100a is set to be larger than the channel cross-sectional area of the refrigerant channel 100b.

The capacitor 51 is connected to a circuit board 60 via electric terminals 51a, 51b (one of the electric terminals is depicted in FIG. 16). In addition, the coil 53 is connected to the circuit board 60 via electric terminals 53a, 53b (one of the electric terminals is depicted in FIG. 16).

The electric terminals 51a, 51b are arranged on the other side in the axial direction of the capacitor 51. The electric terminals 53a, 53b are arranged on the other side in the axial direction of coil 53. Accordingly, the capacitor 51 and the coil 53 are arranged such that the electric terminals 51a, 51b, 53a, 53b face the same direction.

According to the present embodiment that has been described so far, the flat surface 26a and the side surface 26b of the projected section 25 and the flat surface 27a of the bottom section 24 constitute the cooling section 90 for cooling the capacitor 51, the drive circuit 50, the coil 53, and the switching elements SW1 to SW6. Accordingly, each of the drive circuit 50, the capacitor 51, the coil 53, and the switching elements SW1 to SW6 can be brought into contact with an appropriate flat surface of the flat surface 26a and the side surface 26b of the projected section 25 and the flat surface 27a of the bottom section 24 in accordance with a physical constitution thereof. Thus, similar to the above first embodiment, the drive circuit 50, the capacitor 51, and the switching elements SW1 to SW6 can sufficiently be cooled.

In the present embodiment, when the capacitor 51, the coil 53, and the circuit board 60 are assembled in the inverter case 21, similar to the above first embodiment, the capacitor 51 and the coil 53 are accommodated in the inverter case 21 in advance, and the circuit board 60 is then arranged in the inverter case 21. Then, the capacitor 51 is connected to the circuit board 60 via the electric terminals 51a, 51b. Furthermore, the coil 53 is connected to the circuit board 60 via the electric terminals 53a, 53b.

The electric terminals 51a, 51b of the capacitor 51 and the electric terminals 53a, 53b of the coil 53 are arranged to face the same direction (an upper side in FIG. 16). Accordingly, when the capacitor 51 and the coil 53 are assembled to the circuit board 60, the circuit board 60 can be assembled from the same direction with respect to the capacitor 51 and the coil 53. Thus, an assembling process of the circuit board 60 can be simplified.

In the present embodiment, an amount of heat generation of the capacitor 51 is larger than an amount of heat generation of the coil 53. For this reason, the capacitor 51 is in contact with the side surface 26b of the projected section 25 and the flat surface 27a of the bottom section 24. The coil 53 is in contact with the flat surface 27a of the bottom surface 24. That is, the number of the flat surfaces that the capacitor 51 is in contact is larger than the number of the flat surfaces that the coil 53 is in contact. In other words, the capacitor 51 and the coil 53 are set such that the number of contacting flat surfaces differs in accordance with the amount of heat generation. In this way, both of improvement of cooling performance of the capacitor 51 and the coil 53 and downsizing of the inverter case 21 can be achieved in a small space in the inverter case 21.

In the present embodiment, the channel cross-sectional area of the refrigerant channel 100a is set to be larger than the channel cross-sectional area of the refrigerant channel 100b. A flow rate of the refrigerant that flows through the refrigerant channel 100a is lower than a flow rate of the refrigerant that flows through the refrigerant channel 100b. Thus, the switching elements SW1 to SW6, the drive circuit 50, and the capacitor 51, which are in contact with the projected section 25, can reliably be cooled.

### Other Embodiments

In the above third embodiment, the description has been made in which, in the case where the amount of heat generation of the capacitor 51 is larger than the amount of heat generation of the coil 53, the number of the flat surfaces that the capacitor 51 is in contact is increased to be larger than the number of the flat surfaces that the coil 53 is in contact. Instead of the above, the following may be adopted.

More specifically, in the case where the amount of heat generation of the capacitor 51 is smaller than the amount of heat generation of the coil 53, the number of the flat surfaces that the capacitor 51 is in contact may be reduced to be smaller than the number of the flat surfaces that the coil 53 is in contact.

In the above third embodiment, the description has been made on the case where the channel cross-sectional area of the refrigerant channel 100a is set to be larger than the channel cross-sectional area of the refrigerant channel 100b. Instead of the above, the channel cross-sectional area of the refrigerant channel 100a may be set to be smaller than the channel cross-sectional area of the refrigerant channel 100b.

In the above first, second, and third embodiments, a recess or a projection may be provided in the flat surface 26a and the side surface 26b of the projected section 25 and the flat surface 27a of the bottom section 24 in accordance with the physical constitutions of the electronic components, such as the drive circuit 50, the capacitor 51, and the switching elements SW1 to SW6. That is, the electronic components are fitted to the recess(es) or the projection(s) of the flat surfaces (26a, 26b, 27a) of the case 21. In this way, the electronic components can be fixed to the flat surfaces of the case 21, and vibration resistance can thereby be improved.

In the above first, second, and third embodiments, the description has been made on the example in which the refrigerant intake port 23 of the refrigerant channel in the inverter device 20 is provided on a radially outer side with the axis being the center and the refrigerant outlet port 13b is provided on the one side in the axial direction. Instead of the above, the refrigerant intake port 23 may be provided on the other side in the axial direction, and the refrigerant outlet port 13b may be provided on the one side in the axial direction. In this way, a flexibility in design of a connection section between the compressor housing 11 and the inverter case 21 can be increased.

In the above first and second embodiments, the description has been made on the example in which the refrigerant channel is constructed of the plate 13 and the inverter case 21. Instead of the above, the inverter case 21 that is constructed of split cases may be used, and the refrigerant channel may be constructed of the split cases and the plate 13. In this way, assemblability of the drive circuit 50, the capacitor 51, the switching elements SW1 to SW6, and the inverter case 21 can be improved.

In the above first, second, and third embodiments, the description has been made on the example in which the one refrigerant channel is configured in the inverter device 20. Instead of the above, refrigerant channels, through which the refrigerant flows from the evaporator side into the compressor housing 11, may be formed in the inverter device 20. In this way, a flexibility in arrangement of the electronic components can be increased.

In the above first, second, and third embodiments, the description has been made on the example in which a cooling structure for the electronic components is applied to the in-vehicle electric compressor 1. Instead of the above, the cooling structure for the electronic components may be applied to the electric compressor 1 of a mounted type. Alternatively, the cooling structure for the electronic components may be applied to a device other than the electric compressor 1.

It should be appreciated that the present disclosure is not limited to the embodiments described above and can be modified appropriately within the scope of the appended claims. The embodiments above are not irrelevant to one another and can be combined appropriately unless a combination is obviously impossible. In the respective embodiments above, it goes without saying that elements forming the embodiments are not necessarily essential unless specified as being essential or deemed as being apparently essential in principle.

What is claimed is:

1. A cooling structure for electronic components comprising:
a case having a refrigerant intake port and a refrigerant channel through which a refrigerant introduced from the refrigerant intake port flows, the refrigerant channel being formed by a wall section;
a cooling section having a plurality of flat surfaces formed inside of the case in a manner to interpose the wall section between the flat surfaces and the refrigerant channel; and
a plurality of electronic components arranged inside of the case and each of which is in contact with one of the flat surfaces, wherein
each of the electronic components is cooled by the refrigerant via a corresponding flat surface of the flat surfaces and the wall section,
the case includes:
a side wall having a cylindrical shape;
a bottom section arranged on one side in an axial direction of the side wall; and
a projected section arranged on the one side in the axial direction of the side wall and projected from the bottom section to the other side in the axial direction, the projected section closing the one side in the axial direction of the side wall with the bottom section,
the cooling structure for the electronic components further comprises: a plate arranged on the one side in the axial direction with respect to the case to cover the bottom section and the projected section,
a portion of the plate that opposes the projected section has a refrigerant outlet port of the refrigerant channel,
the refrigerant intake port is defined in the side wall, and
the refrigerant channel that communicates with the refrigerant intake port and the refrigerant outlet port is defined between the projected section and the plate.

2. The cooling structure for electronic components according to claim 1, wherein
of the electronic components, the electronic component with a large amount of heat generation is arranged in a portion that is closer to the refrigerant intake port than the electronic component with a small amount of heat generation.

3. The cooling structure for electronic components according to claim 1, wherein
of the electronic components, the electronic component with a large amount of heat generation is set such that the number of contacting flat surfaces of the flat surfaces is larger than that of the electronic component with a small amount of heat generation.

4. The cooling structure for electronic components according to claim 1, wherein
the electronic components are arranged such that electric terminals thereof face the same direction.

5. (canceled)

6. The cooling structure for electronic components according to claim 1, wherein
the case has a recessed section arranged on the one side in the axial direction of the projected section and recessed to the other side in the axial direction, the recessed section communicating with the refrigerant intake port and the refrigerant outlet port,
the plate has a groove arranged at a portion opposing the recessed section on the other side in the axial direction and recessed to the one side in the axial direction to have the refrigerant outlet port, and
the recessed section and the groove define the refrigerant channel.

7. The cooling structure for electronic components according to claim 1, wherein
the flat surfaces have:
a first flat surface arranged on the other side in the axial direction of the projected section; and
a second flat surface that intersects the first flat surface to form a side wall of the projected section.

8. The cooling structure for electronic components according to claim 1, further comprising:
a cooling fin arranged in the refrigerant channel to promote cooling of the electronic components.

9. A cooling structure for electronic components comprising:
a case having a refrigerant intake port and a refrigerant channel through which a refrigerant introduced from the refrigerant intake port flows, the refrigerant channel being formed by a wall section;
a cooling section having a plurality of flat surfaces formed inside of the case in a manner to interpose the wall section between the flat surfaces and the refrigerant channel; and
a plurality of electronic components arranged inside of the case and each of which is in contact with one of the flat surfaces, wherein
each of the electronic components is cooled by the refrigerant via a corresponding flat surface of the flat surfaces and the wall section,
the case includes:
a side wall having a cylindrical shape;
a bottom section arranged on one side in an axial direction of the side wall; and
a projected section arranged on the one side in the axial direction of the side wall and projected from the bottom section to the other side in the axial direction to close the one side in the axial direction of the side wall with the bottom section,
the cooling structure for the electronic components further comprises: a plate arranged on the one side in the axial direction with respect to the case to cover the bottom section and the projected section,
a portion of the plate that corresponds to the projected section has a refrigerant outlet port of the refrigerant channel,
the refrigerant intake port is defined in the side wall,
a first channel that communicates with the refrigerant intake port and a second channel that communicates with the refrigerant outlet port are defined between the projected section and the plate,
a bypass channel is defined between the bottom section and the plate to bypass toward the bottom section from the first channel to communicate with the second channel, and
the first channel, the second channel, and the bypass channel define the refrigerant channel.

10. The cooling structure for electronic components according to claim 9, wherein
the case has:
a first recessed section arranged on the one side in the axial direction of the projected section and recessed to the other side in the axial direction, the first recessed section communicating with the refrigerant intake port;
a second recessed section arranged on the one side in the axial direction of the projected section and recessed to the other side in the axial direction, the second recessed section communicating with the refrigerant outlet port; and
a third recessed section arranged on the one side in the axial direction of the bottom section and recessed to the other side in the axial direction, the third recessed section communicating with the first recessed section and the second recessed section,
the plate has a groove arranged at a portion opposing the first, second, and third recessed sections on the other side in the axial direction and recessed to the one side in the axial direction,
the first recessed section and the groove define the first channel,
the second recessed section and the groove define the second channel, and
the third recessed section and the groove define the bypass channel.

11. The cooling structure for electronic components according to claim 9, wherein
the flat surfaces have:
a first flat surface arranged on the other side in the axial direction of the projected section;
a second flat surface that intersects the first flat surface to form a side wall of the projected section; and
a third flat surface that is formed in the bottom section.

12. The cooling structure for electronic components according to claim 9, further comprising:
a cooling fin arranged in each of the first channel and the second channel to promote cooling of the electronic components.

13. The cooling structure for electronic components according to claim 1, wherein
the refrigerant channel is constructed by the case only.

14. The cooling structure for electronic components according to claim 13, wherein
the case has:
a side wall having a cylindrical shape;
a bottom section arranged on one side in an axial direction of the side wall; and
a projected section arranged on the one side in the axial direction of the side wall and projected from the bottom section to the other side in the axial direction to close the one side in the axial direction of the side wall with the bottom section,
the flat surfaces have:
a first flat surface arranged on the other side in the axial direction of the projected section;
a second flat surface that intersects the first flat surface to form a side wall of the projected section; and
a third flat surface that is formed in the bottom section, and
the refrigerant channel is defined along the first flat surface, the second flat surface, and the third flat surface.

15. An electric compressor including the cooling structure for electronic components according to claim 1, the electric compressor further comprising:
a compression mechanism that compresses the refrigerant discharged from the refrigerant outlet port;
an electric motor that drives the compression mechanism; and
a compressor housing having a cylindrical shape to receive the compression mechanism and the electric motor, wherein
the compressor housing has an axis corresponding to an axis of the case, and the compressor housing is arranged on the one side in the axial direction with respect to the case,
the compressor housing has an opening on the other side in the axial direction, and
the plate is arranged to close the opening of the compressor housing.

16. The electric compressor according to claim 15, wherein
the electronic components define a control circuit that controls the electric motor.
